(19) United States
(12) Patent Application Publication
(10) Pub. No.: US 2008/0233286 A1
(43) Pub. Date: Sep. 25, 2008

(54) Method and apparatus for removing carbonized pitch from the surface of a pitch infiltrated disk

(75) Inventors: Allen H. Simpson, Buchanan, MI (US); Mark L. LaForest, Granger, IN (US); Roger L. Klinedinst, North Liberty, IN (US)

Correspondence Address: HONEYWELL INTERNATIONAL INC.;Law Department AB 2, P.O. Box 2245, Morristown, NJ, 07962-9806, US

(73) Assignee: HONEYWELL INTERNATIONAL INC.

(21) Appl. No.: 11/725,504

(22) Filed: Mar. 20, 2007

(51) Int. Cl. C23C 16/00

(52) U.S. Cl. 427/249.1

(57) ABSTRACT

A device for removing carbonized pitch from first and second parallel surfaces (18, 20) of a pitch infiltrated carbon fiber disk (14) having an axis (16), the device including a disk support (12, 100) for supporting a pitch infiltrated carbon fiber disk (14) at a disk support location on the disk support (12, 100), a first roller support (46, 104) mounted at a first side of the disk support location, a second roller support (46, 104) mounted at a second side of the disk support location, a first roller (58) mounted in the first roller support (46, 104), a second roller (58) mounted in the second roller support (46, 104) and a drive (80, 90. 108) rotating the disk (14) or the first and second roller supports (46, 104) about the central axis. Also a method of removing carbonized pitch from such a disk.

### FIELD OF THE INVENTION

The present invention is directed toward a method and apparatus for removing carbonized pitch from the surface of a pitch infiltrated disk, and, more specifically, toward a method and apparatus for removing carbonized pitch from the surface of a pitch infiltrated disk by pressing rollers against opposite sides of the disk and rotating the disk relative to the rollers.

### BACKGROUND OF THE INVENTION

Products such as brake disks may be formed by providing a non-woven mat or preform of carbon fibers and processing the preform in a furnace in the presence of hydrocarbons such as coal tar pitch which travel through the non-woven mat. Carbon from the pitch bonds with the carbon fibers in the mat and forms a durable, highly heat resistant material that is sometimes referred to as “carbon-carbon.” A process of forming such a carbon-carbon article is described in U.S. Pat. No. 7,063,870, to La Forest, entitled, “Manufacture of Functionally Graded Carbon-Carbon Composites,” the entire contents of which are hereby incorporated by reference.

After a plurality of furnace treatments, the spaces between the carbon fibers are substantially full of carbon atoms, and the carbon atoms and carbon fibers form a very hard product. The hydrocarbons used during the furnace process, however, also protrude from the spaces between the fibers and form a hard, porous, crust on the surfaces of the disk. This crust or flash must be removed before the disks can be used. Currently, the removal of flash may be accomplished by hand using various grinding and/or scraping tools. However, this process is time consuming and labor intensive. Furthermore, it may be difficult to determine where the flash ends and the carbonized preform begins which can lead to the disk being damaged during the deflashing process. It would therefore be desirable to provide a method and apparatus for removing the surface crust or flash in an efficient manner while substantially avoiding damage to the underlying carbon-carbon product.

### SUMMARY OF THE INVENTION

These problems and others are addressed by embodiments of the present invention, a first aspect of which comprises a method of removing carbonized pitch from first and second parallel surfaces of a pitch infiltrated carbon fiber disk. The method involves providing a pitch infiltrated carbon fiber disk having a central axis, pressing a first roller against the first surface of the disk, pressing a second roller against the second surface of the disk, and rotating the disk or the rollers about the central axis of the disk to crush the carbonized pitch.

Another aspect of the invention comprises a device for removing carbonized pitch from the surface of a pitch infiltrated carbon fiber disk. The device includes a disk support for supporting a pitch infiltrated carbon fiber disk for rotation about a central axis in a plane and first and second roller supports mounted on opposite sides of the plane. First and second rollers are mounted in the first and second rollers supports, and a drive is provided for rotating the disk about the central axis between the first and second rollers.

A further aspect of the invention comprises a device for removing carbonized pitch from first and second parallel surfaces of a pitch infiltrated carbon fiber disk. The device includes a disk support for supporting a pitch infiltrated carbon fiber disk at a disk support location on the disk support, a first roller support mounted at a first side of the disk support location and a second roller support mounted at a second side of the disk support location. First and second rollers are mounted in the first and second roller supports, and a drive rotates the disk or the first and second roller supports about a central axis of the disk.

### BRIEF DESCRIPTION OF THE DRAWINGS

These aspects and features of the invention and others will be better understood after a reading of the following detailed description together with the following drawings wherein:

FIG. 1 is a side elevational view illustrating a deflashing device according to a first embodiment of the present invention;

FIG. 2 is an elevational view taken in the direction of line II-II in FIG. 1;

FIG. 3 is an elevational view taken in the direction of line III-III in FIG. 1;

FIG. 4 is a side elevational view illustrating a deflashing device according to a second embodiment of the present invention;

FIG. 5 is a side elevational view illustrating a deflashing device according to a third embodiment of the present invention;

FIG. 6 is top plan view of a roller usable in the deflashing device of FIG. 1;

FIG. 7 is a front elevational view of the roller of FIG. 5;

FIG. 8 is a side elevational view of the roller of FIG. 5;

FIG. 9 is a side elevational view of a deflashing device according to a fourth embodiment of the present invention; and

FIG. 10 illustrates a method of deflashing a pitch infiltrated carbon fiber disk according to an embodiment of the invention.

### DETAILED DESCRIPTION

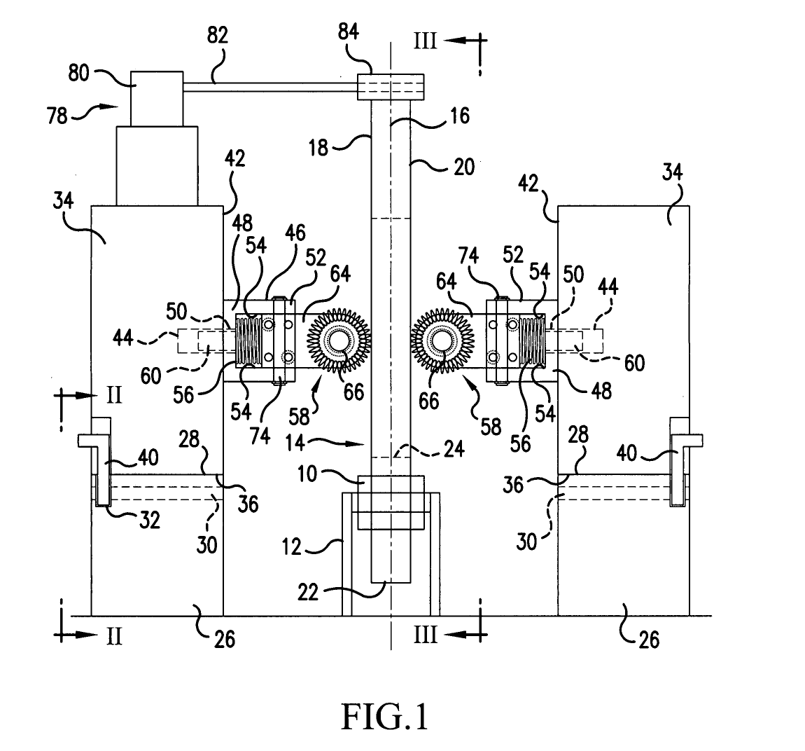

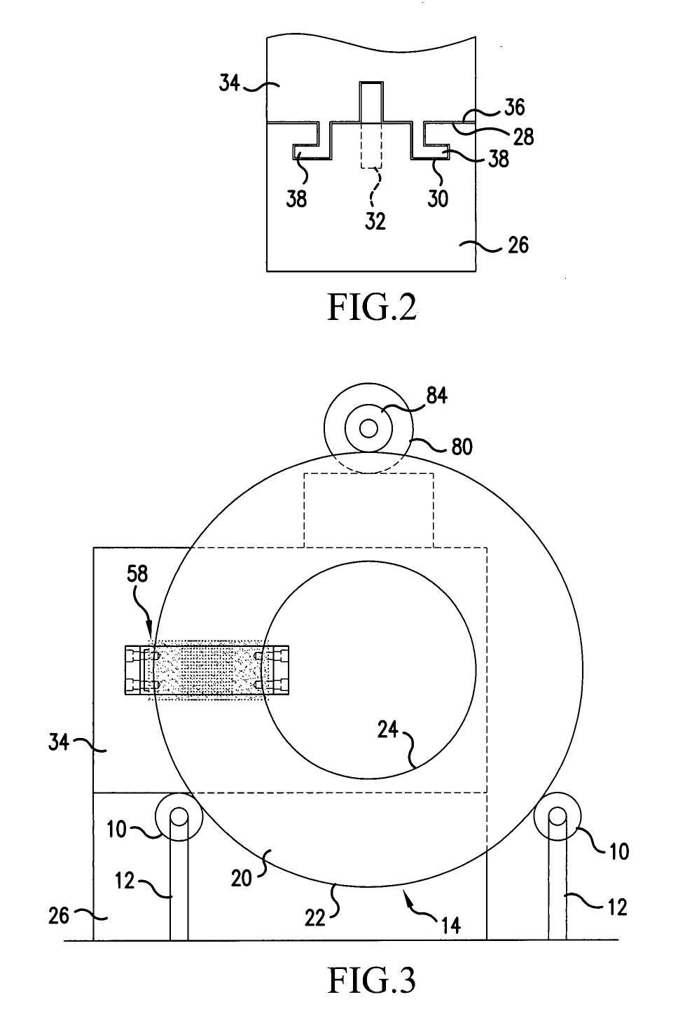

Referring now to the drawings, wherein the showings are for purposes of illustrating embodiments of the invention only and not for the purpose of limiting same, FIGS. 1-3 illustrate a deflashing device that comprises first and second support rollers 10 mounted on first and second support frames 12 for supporting a disk 14 for rotation in a vertical plane 16. Disk 14 has a first surface 18 substantially parallel to a second disk surface 20, an outer peripheral surface 22 that rests on support roller 10 and an inner peripheral surface 24. Base members 26 are mounted on opposite sides of support frames 12. One base member 26 and the elements supported thereby will be described hereinafter; the other one of the base members 26 is substantially identical to the first base member 26 and will not be separately described. The same reference numerals are used to designate elements found on both sides of the support rollers 10.

Base member 26 has a generally planar upper surface 28 having first and second L-shaped grooves 30 and a bore 32 therein. A slider 34 having a bottom surface 36 from which project first and second L-shaped legs 38 is mounted on base member 26 with first and second L-shaped legs 38 slidably received in the first and second L-shaped grooves 30 and bottom surface 36 resting on upper surface 28 so that slider 34 can move relative to base member 26 in the longitudinal direction of the grooves 30 but not in a direction normal to the longitudinal direction of the grooves 30. A retaining pin 40 is slidably supported on slider 34 and is insertable in bore 32 in base member 26 to selectively prevent sliding movement between the slider 34 and the base member 26. More than one bore 32 may be provided to allow for finer adjustments in the relative positions of slider 34 and base 26. Other arrangements for adjustably mounting a slider on a base member could also be used without departing from the scope of the present invention.

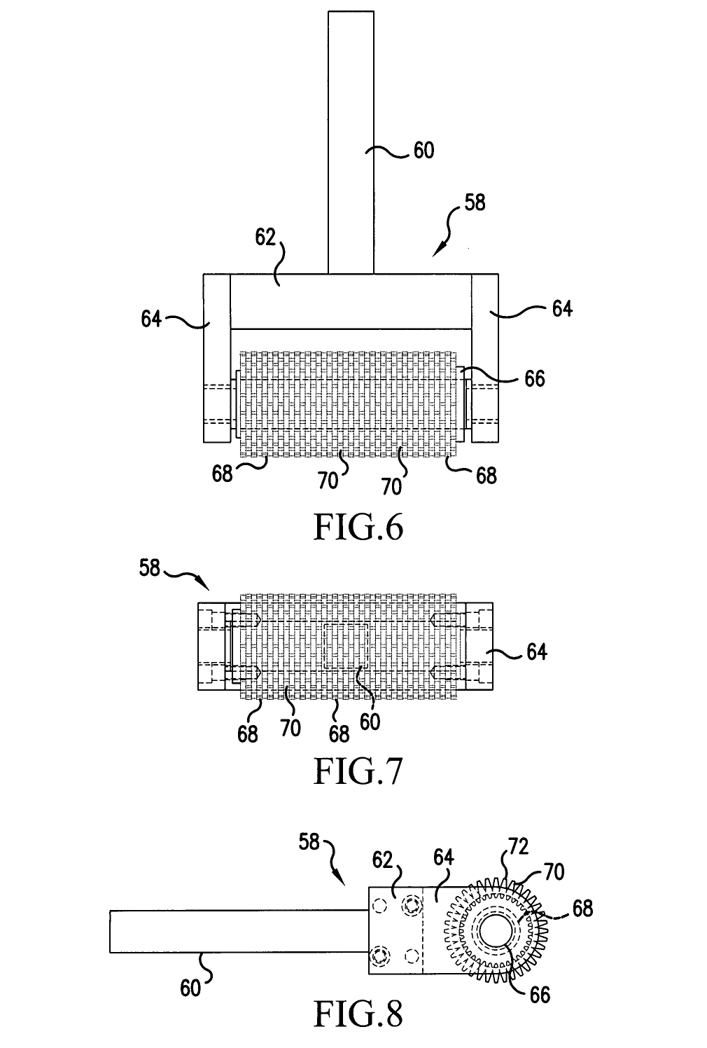

Slider 34 includes a side face 42 having a side bore 44 and a roller support 46 having a back wall 48 having an opening 50 mounted on side face 42 with roller support opening 50 aligned with side face bore 44. Roller support 46 includes first and second side walls 52 having opposed inner surfaces 54 and a spring 56 supported therebetween. A roller 58, illustrated apart from the deflashing system in FIGS. 6-8, includes a shaft 60, a body 62 connected to shaft 60, and first and second arms 64 projecting from body 62 which arms 64 rotatably support a rolling member 66. Rolling member 66 comprises a plurality of wheels 68 each including a plurality of projecting teeth 70 having flat distal ends 72. The teeth 70 of adjacent wheels are staggered or offset from each other. With reference to FIG. 1, roller 58 is mounted in roller support 46 with roller shaft 60 passing through roller support opening 50 and slidably into side bore 44 of slider 34. Roller body 62 slidably engages inner surfaces 54 of roller support 46 and first and second pins 74 retain roller 58 in roller support 46. Spring 56 biases roller 58 away from slider 34.

A drive mechanism 78 comprising a motor 80 driving a shaft 82 is mounted on one of the sliders 34 and includes a drive roller 84 for frictionally engaging the outer peripheral surface 22 of disk 14.

In use, a disk 14 is placed onto support rollers 10 and the sliders 34 on opposite sides of the disk are moved relative to base members 26 to bring first and second rollers 58 into contact with the opposite parallel surfaces 18, 20 of disk 14 and to compress springs 5 to apply a desired biasing force against the first and second sides 18, 20. The force applied against disk 14 may be adjusted by a proper selection of spring strength and the relative positions of the sliders 46 and base members 26. A typical amount of force applied by the rollers might be, for example, fifty pounds. Drive roller 84 is brought into engagement with outer peripheral edge 22 of the disk and driven to cause disk 14 to rotate on its central axis on support rollers 10 between the opposed rollers 58. The flat ends 72 of teeth 70 on rolling members 66 crush the carbonized pitch on the surfaces of the disk 14 as disk 14 rotates between rotating rolling members 58. Preferably, disk 14 is mounted in a vertical orientation as illustrated in the drawing figures so that the crushed pitch falls away from disk 14 and is not ground into the surface. The portion of the disk 14 that includes reinforcing fibers is harder than the excess carbonized pitch and is not crushed or damaged by contact with the turning rolling members 58. The disk 14 is rotated in this manner until all or a substantial amount of the carbonized pitch is broken free from the disk 14 after which disk 14 is removed from the support rollers 10 for further conventional processing.

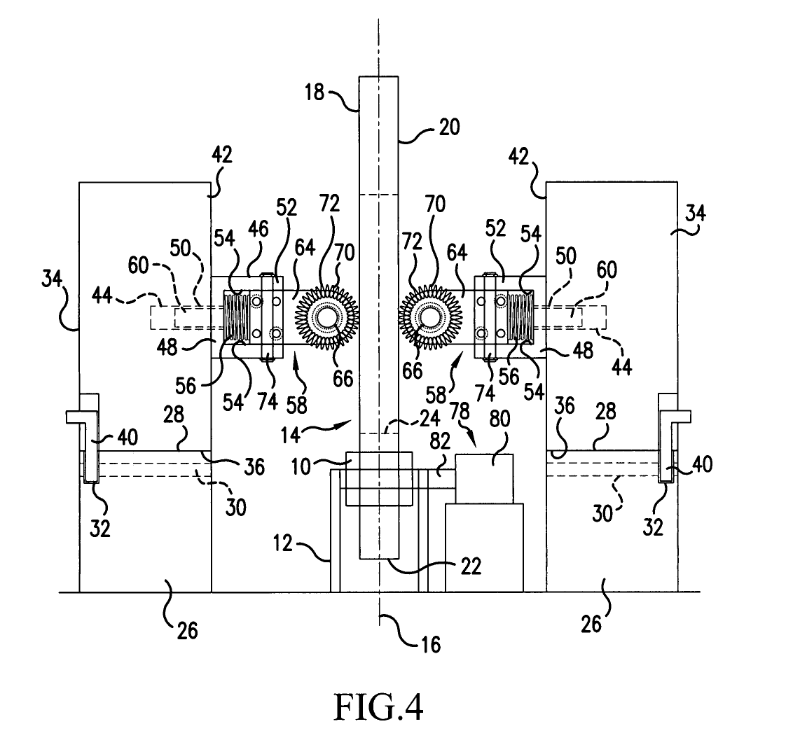

A second embodiment of the present invention is illustrated in FIG. 4 which second embodiments differs from the first embodiment in the location of the drive mechanism 78. The same reference numerals are used to illustrate elements common to the first embodiment. In FIG. 4, the shaft 82 of motor 80 is operatively connected to one of the support rollers 10 to directly drive the support roller 10 and the disk 14 supported thereon. The processing of disk 14 is otherwise identical to the processing described above in connection with the first embodiment.

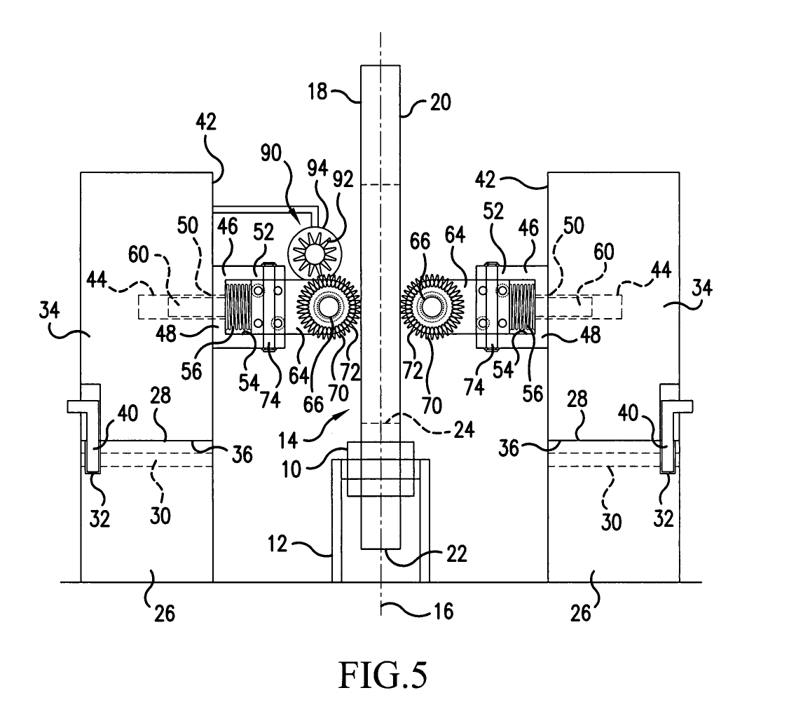

A third embodiment of the present invention is illustrated in FIG. 5 which differs from the first and second embodiments in the location of the drive mechanism. The same reference numerals are used to illustrate elements common to the first and second embodiments. In FIG. 5, a drive mechanism 90 is mounted on one of sliders 34 and includes a drive gear 92 driven by a motor 94 which drive gear 92 directly engages rolling members 66 to turn the rolling members and hence disk 14. Except for this different driving mechanism, the operation of the deflashing device of the third embodiment is substantially the same as the operation of the first and second embodiments.

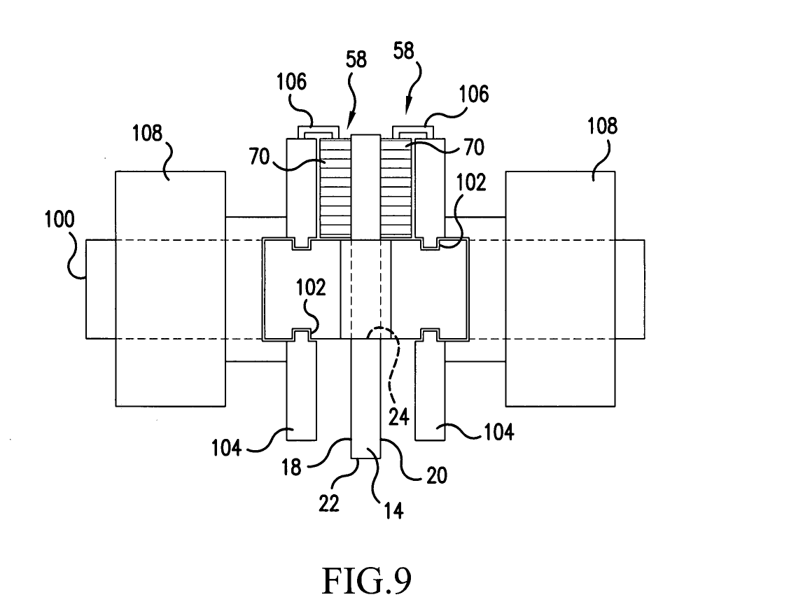

A fourth embodiment of the present invention is illustrated in FIG. 9. As described hereafter, in this embodiment, disk 14 is held in a fixed position while first and second rollers 58 are driven around the central axis of disk 14. The same reference numerals are used to illustrate elements common to the first, second and third embodiments. Disk 14 is mounted on support shaft 100 so that inner peripheral surface 24 of the disk is in contact with the shaft 100. Shaft 100 includes guide channels 102 on opposite sides of disk 14 in which rotatable roller supports 104 are mounted. Rolling members 66 having wheels 68 are supported from arms 106 on roller supports 104. A motor 108 drives rollers supports 104 around the axis of the support shaft 100 to press rolling members 66 against the carbonized pitch on the parallel surfaces 18, 20 of disk 14. The location of motors 108 on support shaft 100 can be varied to control the pressure exerted by the rolling members 66 against the disk. Motors 108 are preferably synchronized so that the first and second rolling members 66 remain opposite each other as they travel around the axis of the disk 14 to provide balanced pressure on each side of the disk 14.

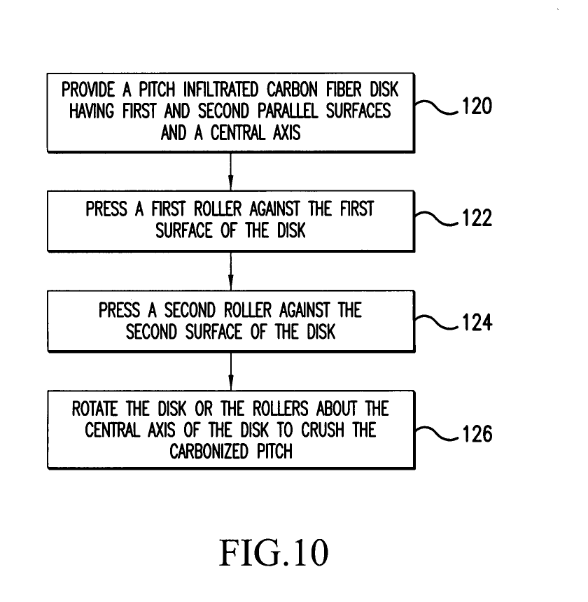

A method according to an embodiment of the present invention is illustrated in FIG. 10 and includes a step 120 of providing a pitch infiltrated carbon fiber disk having first and second parallel surfaces and a central axis, a step 122 of pressing a first roller against the first surface, a step 124 of pressing a second roller 124 against the second surface and a step 126 of rotating the disk or the rollers about the central axis of the disk to crush the carbonized pitch.

The present invention has been described herein in terms of several presently preferred embodiments. Modifications and additions to these embodiments will become apparent to those of ordinary skill in the art upon reading of the foregoing description. It is intended that all modifications and additions to these embodiments form a part of the present invention to the extent they fall within the scope of the several claims appended hereto.

We claim:

1. A method of removing carbonized pitch from first and second parallel surfaces of a pitch infiltrated carbon fiber disk comprising the steps of:
providing a pitch infiltrated carbon fiber disk having a central axis;
pressing a first roller against the first surface of the disk;
pressing a second roller against the second surface of the disk; and
rotating the disk or the rollers about the central axis of the disk to crush the carbonized pitch.

2. The method of claim 1 wherein said step of rotating the disk or the rollers about the central axis of the disk comprises the step of rotating the disk.

3. The method of claim 2 including the additional step of providing at least one support roller and placing an edge of the disk on the at least one support roller.

4. The method of claim 1 wherein said step of pressing a second roller against the second surface of the disk comprises the step of pressing a second roller against the disk directly opposite the first roller.

5. The method of claim 2 wherein said step of rotating the disk comprises the step of driving at least one of said first and second rollers.

6. The method of claim 2 wherein said step of rotating the disk comprises the step of driving at least one of the at least one support roller.

7. The method of claim 1 wherein said step of providing a first roller comprises the step of providing a first roller having a toothed surface.

8. The method of claim 1 wherein said step of pressing a first roller against the disk comprises the step of spring biasing the first roller against the disk with a given force.

9. A device for removing carbonized pitch from the surface of a pitch infiltrated carbon fiber disk comprising:
a disk support for supporting a pitch infiltrated carbon fiber disk for rotation about a central axis in a plane;
a first roller support mounted at a first side of said plane;
a second roller support mounted at a second side of said plane;
a first roller mounted in said first roller support;
a second roller mounted in said second roller support; and
a drive rotating the disk about the central axis between the first and second rollers.

10. The device of claim 9 wherein said disk support comprises at least one support roller.

11. The device of claim 9 wherein said first roller is slidably mounted in said first roller support.

12. The device of claim 11 wherein said first roller is spring biased away from the first roller support.

13. The device of claim 9 wherein said first roller is slidably mounted in said first roller support, said second roller is slidably mounted in said second roller support and wherein said first roller and second roller are spring biased toward each other.

14. The device of claim 9 wherein said first roller includes a plurality of radially projecting tooth members.

15. The device of claim 9 wherein said first roller comprises a plurality of toothed disks mounted for rotation about a common axis.

16. The device of claim 15 wherein the teeth of a first one of said plurality of toothed disks are offset from the teeth of an adjacent one of said plurality of toothed disks.

17. The device of claim 10 wherein said drive is operably connected to said at least one support roller.

18. The device of claim 9 wherein said drive is operably connected to said first roller.

19. A device for removing carbonized pitch from first and second parallel surfaces of a pitch infiltrated carbon fiber disk having an axis comprising:
a disk support for supporting a pitch infiltrated carbon fiber disk at a disk support location on the disk support;
a first roller support mounted at a first side of said disk support location;
a second roller support mounted at a second side of said disk support location;
a first roller mounted in said first roller support;
a second roller mounted in said second roller support; and
a drive rotating the disk or the first and second roller supports about the central axis.

20. The device of claim 19 including a first spring mounted between said first roller and said first roller support and a second spring mounted between said second roller and said second roller support, said first and second springs biasing said first and second rollers toward each other.
